(19) United States
(12) Patent Application Publication
(10) Pub. No.: US 2021/0296236 A1
(43) Pub. Date: Sep. 23, 2021

(54) SEMICONDUCTOR MEMORY DEVICE

(71) Applicant: KIOXIA CORPORATION, Tokyo (JP)

(72) Inventor: Kaito SHIRAI, Nagoya Aichi (JP)

(21) Appl. No.: 17/005,267

(22) Filed: Aug. 27, 2020

(30) Foreign Application Priority Data
Mar. 19, 2020 (JP) 2020-049267

(51) Int. Cl. H01L 23/535; H01L 27/11565; H01L 27/1157; H01L 27/11582; H01L 27/11573; H01L 23/522; H01L 23/528; H01L 23/532; H01L 21/768

(52) U.S. Cl. CPC H01L 23/535; H01L 27/11565; H01L 27/1157; H01L 27/11582; H01L 21/76895; H01L 23/5226; H01L 23/5283; H01L 23/53257; H01L 21/76805; H01L 27/11573

(57) ABSTRACT

According to one embodiment, a semiconductor memory device includes a first conductor layer above a substrate and a plurality of second conductor layers stacked above the first conductor layer. The second conductor layers are spaced from each other. Pillars extend through the plurality of second conductor layers. Each pillar includes a semiconductor layer that is electrically connected to the first conductor layer. A first metal plug is provided to surround an outer circumference of the first conductor layer and electrically connect the first conductor layer to the substrate.

### CROSS-REFERENCE TO RELATED APPLICATION(S)

This application is based upon and claims the benefit of priority from Japanese Patent Application No. 2020-049267, filed Mar. 19, 2020, the entire contents of which are incorporated herein by reference.

### FIELD

Embodiments described herein relate generally to a semiconductor memory device.

### BACKGROUND

A NAND flash memory is known type of a semiconductor memory device.

### BRIEF DESCRIPTION OF THE DRAWINGS

FIG. 1 is a block diagram of a semiconductor memory device according to a first embodiment.

FIG. 2 is a circuit diagram of a memory cell array in a semiconductor memory device according to a first embodiment.

FIG. 3 is a plan view illustrating an example of a planar layout of a memory cell array in a semiconductor memory device according to a first embodiment.

FIG. 4 is a cross-sectional view of a memory cell array taken along a line A1-A2 of FIG. 3.

FIG. 5 is a schematic depiction of a three-dimensional structure of a source line in a memory cell array in a semiconductor memory device according to a first embodiment.

FIG. 6 is a flowchart of a method of manufacturing a semiconductor memory device according to a first embodiment.

FIG. 7 is a flowchart of a method of manufacturing a semiconductor memory device according to a first embodiment.

FIGS. 8-31 are cross-sectional views of a memory cell array illustrating aspects of a manufacturing process of a semiconductor memory device according to a first embodiment.

FIG. 32 is a flowchart of a method of manufacturing a semiconductor memory device according to a second embodiment.

FIGS. 33-35 are a cross-sectional views of a memory cell array illustrating aspects of a manufacturing process of a semiconductor memory device according to a second embodiment.

FIG. 36 is a cross-sectional view illustrating a modification of a memory cell array taken along a line A1-A2 of FIG. 3.

### DETAILED DESCRIPTION

In general, according to one embodiment, a semiconductor memory device includes a first conductor layer that is above a substrate in a first direction. A plurality of second conductor layers are stacked above the first conductor layer in the first direction. The second conductor layers are spaced from each other in the first direction. A plurality of pillars extends through the plurality of second conductor layers in the first direction. Each pillar included¥s a semiconductor layer electrically connected to the first conductor layer. A first metal plug is provided to surrounds an outer circumference or outer perimeter of the first conductor layer. The first metal plug electrically connects the first conductor layer to the substrate.

Hereinafter, example embodiments will be described with reference to the drawings. Each depicted embodiment exemplifies an apparatus or a method embodying one or more technical concepts of the present disclosure. The drawings are schematic and/or conceptual, and, as such, depicted dimensions and proportions of aspect in the drawings are not always the same as actual dimensions and proportions of such aspects. The technical concepts of the present disclosure are not limited to the depicted shapes, structures, arrangements, or the like of components in the drawings and/or example embodiments.

In the following description, components having substantially the same functions and configurations are denoted by the same reference symbols. For certain aspects having multiple instances, suffixes may be appended to a base reference symbol to distinguish between the different instances. When suffixes are not appended to such base reference symbols, associated description applies to each instance

### 1. First Embodiment

In the following example, a case where the semiconductor memory device is a NAND flash memory capable of storing data in a nonvolatile manner will be described.

### 1.1. Configuration of Semiconductor Memory Device 1

### 1.1.1 Overall Configuration of Semiconductor Memory Device 1

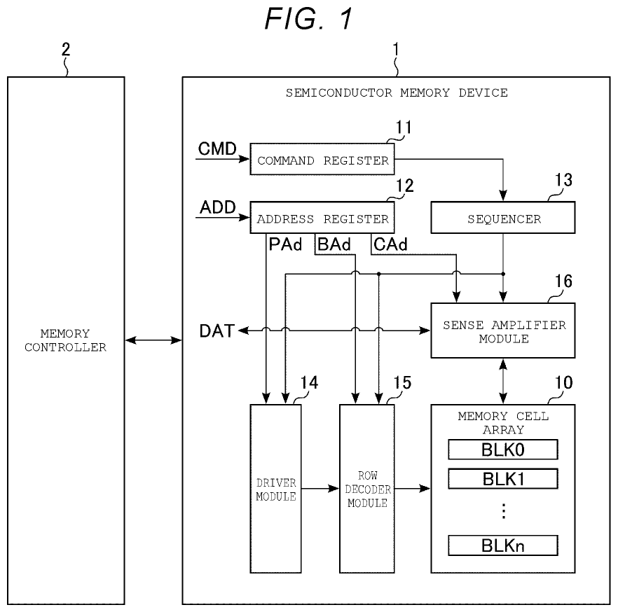

The overall configuration of the semiconductor memory device 1 will be described with reference to FIG. 1. FIG. 1 illustrates a configuration example of the semiconductor memory device 1 according to the first embodiment.

As illustrated in FIG. 1, the semiconductor memory device 1 is controlled by an external memory controller 2. The semiconductor memory device 1 includes a memory cell array 10, a command register 11, an address register 12, a sequencer 13, a driver module 14, a row decoder module 15, and a sense amplifier module 16.

The memory cell array 10 includes a plurality of blocks BLK0 to BLKn (where n is an integer equal to or greater than 1). A plurality of bit lines and a plurality of word lines are provided in the memory cell array 10. The block BLK is a set of non-volatile memory cells, and is used, for example, as a data erasing unit. Each memory cell is associated with one bit line and one word line. A detailed configuration of the memory cell array 10 will be described later.

The command register 11 stores a command CMD, which is received by the semiconductor memory device 1 from the memory controller 2. The command CMD is, for example, an instruction that causes the sequencer 13 to execute a read operation, a write operation, an erasing operation, or the like.

The address register 12 stores address information ADD, which is received by the semiconductor memory device 1 from the memory controller 2. The address information ADD is, for example, a block address BAd, a page address PAd, and a column address CAd. The block address BAd, the page address PAd, and the column address CAd are respectively used to select the block BLK, the word line, and the bit line.

The sequencer 13 controls the overall operation of the semiconductor memory device 1. For example, the sequencer 13 executes a read operation, a write operation, an erasing operation, or the like by controlling the driver module 14, the row decoder module 15, the sense amplifier module 16, and the like based on the command CMD stored in the command register 11.

The driver module 14 generates a voltage used in a read operation, a write operation, an erasing operation, or the like. The driver module 14 applies the generated voltage to each of a signal line corresponding to the selected word line and a signal line corresponding to the non-selected word line, based on the page address PAd stored in the address register 12.

The row decoder module 15 selects one block BLK based on the block address BAd stored in the address register 12. The row decoder module 15 transmits, for example, the voltage applied to each of the signal line corresponding to the selected word line and the signal line corresponding to the non-selected word line, to the selected word line and the non-selected word line in the selected block BLK.

In the write operation, the sense amplifier module 16 applies a voltage to each bit line according to write data DAT received from the memory controller 2. Further, in the read operation, the sense amplifier module 16 determines the data stored in the memory cell based on the voltage of the bit line, and transmits the determination result to the memory controller 2, as read data DAT.

The semiconductor memory device 1 and the memory controller 2 described above may be combined into one semiconductor device. Examples of such a semiconductor device include a memory card such as an SD (registered trademark) card, a solid state drive (SSD), and the like.

### 1.1.2 Circuit Configuration of Memory Cell Array 10

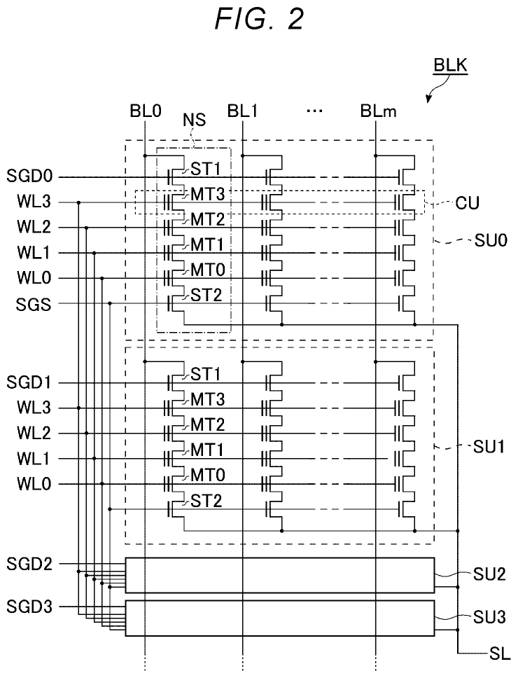

Next, an example of a circuit configuration of the memory cell array 10 will be described with reference to FIG. 2. FIG. 2 illustrates an example of a circuit configuration of the memory cell array 10 in the semiconductor memory device 1 according to the first embodiment, and illustrates one block BLK extracted from the plurality of blocks BLK in the memory cell array 10.

As illustrated in FIG. 2, the block BLK includes, for example, four string units SU0 to SU3. The number of string units SU in each block BLK may be any number. Each string unit SU includes a plurality of NAND strings NS respectively associated with the bit lines BL0 to BLm (where m is an integer equal to or greater than 1).

The NAND string NS includes, for example, four memory cell transistors MT0 to MT3 and select transistors ST1 and ST2. The number of the memory cell transistors MT and the select transistors ST1 and ST2 in each NAND string NS may be any number.

The memory cell transistor MT includes a control gate and a charge storage layer, and stores data in a nonvolatile manner. Each of the select transistors ST1 and ST2 is used to select the string unit SU in various operations.

In each NAND string NS, the memory cell transistors MT0 to MT3 are connected in series between the source of the select transistor ST1 and the drain of the select transistor ST2. The control gates of the memory cell transistors MT0 in the same block BK are connected in common to the word line WL0, likewise for the memory cell transistors MT1 and the word line WL1, for the memory cell transistors MT2 and word line WL2, and for the memory cell transistors MT3 and the word line WL3.

The gates of the select transistors ST1 in each of the string units SU0 to SU3 in the same block BLK are respectively connected to select gate lines SGD0 to SGD3. The drains of the select transistors ST1 in the same column in the plurality of blocks BLK are connected to the same corresponding bit line BL.

The gates of the select transistors ST2 in the same block BLK are connected in common to a select gate line SGS. The sources of the select transistors ST2 in each string unit SU are connected in common to a source line SL, which may be shared by the plurality of blocks BLK.

The plurality of memory cell transistors MT connected to the common word line WL in one string unit SU are called, for example, a cell unit CU. The storage capacitance of each cell unit CU changes according to the number of bits of the data stored in the memory cell transistor MT.

For example, one cell unit CU can store one-page data when each memory cell transistor MT stores 1-bit data, and can store two-page data when each memory cell transistor MT stores 2-bit data.

In this way, “one-page data” is defined, for example, by the total amount of data stored in the cell unit CU including the memory cell transistors MT that store 1-bit data.

### 1.1.3 Structure of Memory Cell Array 10

Hereinafter, an example of a structure of the memory cell array 10 in the semiconductor memory device 1 according to the first embodiment will be described.

In the drawings, an X direction corresponds to an extending direction of the word line WL, a Y direction corresponds to an extending direction of the bit line BL, and a Z direction corresponds to a vertical direction with respect to a surface of a p-type semiconductor substrate (hereinafter, simply referred to as “semiconductor substrate”) on which the semiconductor memory device 1 is formed. This surface of the semiconductor substrate may be referred to as a front surface or an upper surface. Likewise other layers and elements may be described as having a front/upper surface or back/lower surface. Such description is for convenience and does not necessarily imply any particular orientation with respect to gravity or the like of the described devices, layers, elements, etc. For easier understanding of the drawings, hatching is sometimes added to component in the plan view. The hatching added to the plan view is not necessarily related to a material composition and/or any characteristic of the hatched component. In the cross-sectional views, certain components such as an insulating layer (interlayer insulating film), wiring, and a contact plug may be omitted as appropriate for depictional clarity.

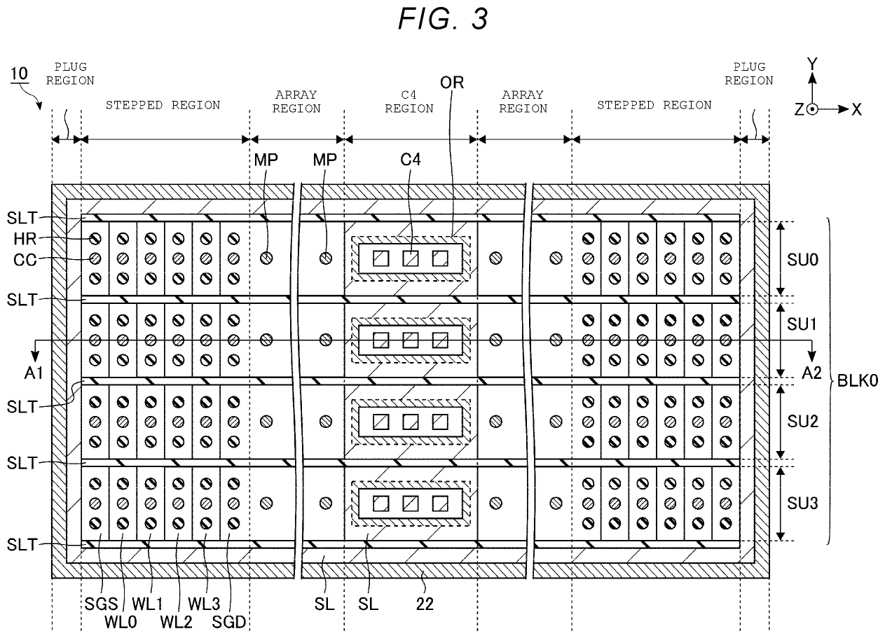

FIG. 3 illustrates an example of a planar layout of the memory cell array 10 according to the first embodiment, and illustrates structures corresponding to the block BLK0 among the plurality of blocks BLK. The bit line BL and the interlayer insulating film are omitted.

As illustrated in FIG. 3, the structures corresponding to each of the string units SU0 to SU3 of the block BLK0 extend in the X direction, and are arranged with respect to each other along the Y direction. The structures corresponding to each of the string units SU0 to SU3 are separated from each other by slits SLT. That is, the string unit SU extending in the X direction is provided between two slits SLT adjacent to each other in the Y direction. In other words, the plurality of slits SLT extending in the X direction are arranged with respect to each other along the Y direction. The structure between by the adjacent slits SLT in the Y direction corresponds to one string unit SU. For example, the structure corresponding to the string unit SU is divided into two portions by a C4 region, which is interposed between the two portions along the X direction.

A conductor corresponding to the source line SL is provided in a lower layer of the structure corresponding to the string unit SU. A metal plug 22 is in contact with a side surface of the conductor corresponding to the source line SL and surround an outer circumference of the conductor corresponding to the source line SL.

The memory cell array 10 includes an array region, a stepped region, the C4 region, and a plug region. First, a detailed structure of the array region will be described.

The array region is a region in which data is substantially stored. A plurality of memory pillars MP are provided in the array region. Each of the memory pillars MP functions as, for example, one NAND string NS. The number of the memory pillars MP illustrated in FIG. 3 is mere an example, and the number of the memory pillars MP is not limited to this number. The plurality of the memory pillars MP may be provided in a staggered pattern.

Next, a detailed structure of the stepped region will be described.

The stepped region is a region for electrically connecting the word lines WL and the select gate lines SGD and SGS connected to the memory pillar MP provided in the array region, to the row decoder module 15.

In the stepped region, a plurality of conductors respectively corresponding to the select gate line SGS, the word lines WL0 to WL3, and the select gate line SGD from the lower layer are provided, for example, in a stepped shape.

Further, in the stepped region, a plurality of contact plugs CC are provided corresponding to, for example, the select gate line SGS, the word lines WL0 to WL3, and the select gate line SGD. The plurality of conductors respectively corresponding to the select gate line SGS, the word lines WL0 to WL3, and the select gate line SGD are electrically connected to the row decoder module 15 through the corresponding contact plugs CC.

In the stepped region, a plurality of dummy pillars HR, which penetrate at least one of the conductors 23 to 28 and of which the bottom surface reaches the conductor corresponding to the source line SL, are provided. The dummy pillars HR are arranged in any manner. The dummy pillar HR is not electrically connected to other wirings. The dummy pillar HR functions as a pillar that supports the interlayer insulating film when a gap is formed in a manufacturing process.

Next, a detailed structure of the C4 region will be described.

The C4 region is a region for connecting an electrode (wiring) provided above the memory cell array 10 and a circuit portion provided below the memory cell array 10. In the C4 region, a plurality of contact plugs C4, which connect the electrode provided above the memory cell array 10 and the circuit portion provided below the memory cell array 10, are provided. In the C4 region, an opening region OR is provided in the conductor corresponding to the source line SL, the opening region OR being a region for allowing the contact plugs C4 to pass through the conductor. Since the contact plugs C4 pass through the opening region OR, the contact plugs C4 are not electrically connected to the conductor corresponding to the source line SL. In the opening region OR, a metal plug 22 is provided between the conductor corresponding to the source line SL and the contact plug C4 so as to be in contact with the side surface of the conductor corresponding to the source line SL. The number of the contact plugs C4 illustrated in FIG. 3 is mere an example, and the number of the contact plugs C4 is not limited to this number.

Next, a structure of the plug region will be described.

The plug region is a region in which the metal plug 22 is in contact with the side surface of the conductor corresponding to the source line SL and surround the outer circumference of the conductor corresponding to the source line SL. In the plug region, the conductor corresponding to the source line SL is electrically connected to an impurity diffusion layer region provided on the semiconductor substrate.

FIG. 4 is a cross-sectional view taken along a line A1-A2 of FIG. 3, and illustrates an example of a structure of the memory cell array 10 according to the first embodiment. Some of the insulating layers are omitted from FIG. 4.

As illustrated in FIG. 4, the memory cell array 10 in the array region includes a conductor 21, conductors 23 to 28, and the plurality of memory pillars MP.

The conductor 21 is provided above the semiconductor substrate 20 with an insulating layer interposed therebetween. The conductor 21 is formed, for example, in a plate shape spreading along an XY plane. The conductor 21 functions as the source line SL. The conductor 21 is, for example, polysilicon (poly-Si). In a region between the semiconductor substrate 20 and the conductor 21, circuits such as the row decoder module 15 and the sense amplifier module 16 are provided, and the circuits include a plurality of control transistors and the like. The control transistor controls, for example, the memory cell array 10 provided above the semiconductor substrate 20. In FIG. 4, only two N-channel MOS transistors Tr are illustrated as an example of the control transistor.

For example, a P-type well region and an element isolation area STI are provided in the semiconductor substrate 20 near the upper surface of the semiconductor substrate 20.

Each of the P-type well region and the element isolation area STI is in contact with the upper surface of the semiconductor substrate 20. The element isolation area STI electrically isolates, for example, an N-type well region and the P-type well region. For the element isolation area STI, for example, silicon oxide is used.

The N-channel MOS transistor Tr includes two N⁺ impurity diffusion layer regions, an insulating layer OX, a gate electrode GC, and an insulating layer SW.

The two N⁺ impurity diffusion layer regions are formed at an upper surface of the P-type well region, and are doped with, for example, phosphorus (P). One N³⁰ impurity diffusion layer region is disposed apart from the other N⁺ impurity diffusion layer region in the X direction. The two N⁺ impurity diffusion layer regions function as a source (source diffusion layer) and a drain (drain diffusion layer) of the N-channel MOS transistor Tr.

The insulating layer OX is provided on the P-type well region between the two N⁺ impurity diffusion layer regions, and functions as a gate insulating film of the N-channel MOS transistor Tr. The insulating layer OX is formed using an insulating material, and the insulating material can be, for example, a stacked structure of silicon oxide and silicon nitride layers.

The gate electrode GC is provided on the insulating layer OX.

The insulating layer SW is provided on a side surface of the gate electrode GC of the N-channel MOS transistor Tr, and functions as a sidewall.

Contact plugs C1 and CS and a wiring layer D1 are provided above the N-channel MOS transistor Tr.

The contact plug C1 is a conductor provided between the gate electrode GC of the N-channel MOS transistor Tr and the wiring layer D1. The contact plug CS is a conductor provided between the source or the drain of the N-channel MOS transistor Tr and the wiring layer D1. Each of the two N⁺ impurity diffusion layer regions is electrically connected to the wiring layer D1 through the contact plug CS. The gate electrode GC is electrically connected to the wiring layer D1 through the contact plug C1.

The conductors 23 to 28 are sequentially provided above the conductor 21 from the lower layer with insulating layers interposed therebetween. The conductors 23 to 28 are separated from each other in the Z direction. The conductors 23 to 28 are formed, for example, in a plate shape extending in the X direction. The conductors 23 to 28 are respectively used as the select gate line SGS, the word lines WL0 to WL3, and the select gate line SGD. The conductors 23 to 28 comprise, for example, tungsten (W).

The memory pillar MP is formed in a columnar shape extending along the Z direction. The memory pillar MP penetrates the conductors 23 to 28, and the bottom surface of the memory pillar MP is inside the conductor 21. The memory pillar MP does not penetrate beyond the conductor 21.

The memory pillar MP includes, for example, a core member 29, a semiconductor 30, insulating layers 31 to 33, and a conductor 34.

The core member 29 is formed at the center portion of the memory pillar MP in a columnar shape extending along the Z direction. A lower end of the core member 29 is disposed in the conductor 21. The core member 29 comprises silicon dioxide (SiO₂), for example.

Aside surface and a bottom surface of the core member 29 are covered with the semiconductor 30. A part of a side surface of the semiconductor 30 is in contact with the conductor 21, and is electrically connected to the conductor 21. The semiconductor 30 functions as a channel of each of the memory cell transistor MT and the select transistors ST1 and ST2. The semiconductor 30 comprises, for example, poly-Si.

A part of the side surface and a bottom surface of the semiconductor 30 are covered with stacked films of insulating layers 31 to 33. The insulating layer 31 is in contact with the semiconductor 30, and surrounds the side surface and the bottom surface of the semiconductor 30. The insulating layer 31 functions as a tunnel insulating film of the memory cell transistor MT. The insulating layer 31 is, for example, SiO₂.

The insulating layer 32 is in contact with the insulating layer 31, and surrounds a side surface and a bottom surface of the insulating layer 31. The insulating layer 32 functions as a charge storage layer of the memory cell transistor MT. The insulating layer 32 is, for example, silicon nitride (SiN).

The insulating layer 33 is in contact with the insulating layer 32, and surrounds a side surface and a bottom surface of the insulating layer 32. The stacked films of the insulating layers 31 to 33 are not provided in a region in which the semiconductor 30 and the conductor 21 are in contact with each other. The insulating layer 33 functions as a block insulating film of the memory cell transistor MT. The insulating layer 33 is, for example, SiO₂.

The conductor 34 is formed on upper portions of the core member 29 and the semiconductor 30. The conductor 34 is electrically connected to the semiconductor 30. The side surface of the conductor 34 is covered with stacked films of the insulating layers 31 to 33. The conductor 34 comprises, for example, poly-Si, and may be integrally formed with the semiconductor 30.

In the above-described configuration, a portion of the memory pillar MP that intersects with the conductor 23 functions as the select transistor ST2. Portions of the memory pillar MP that intersects with each of the conductors 24 to 27 function as the memory cell transistors MT0 to MT3, respectively. A portion of the memory pillar MP that intersects with the conductor 28 functions as the select transistor ST1.

The memory pillar MP may have a structure in which pillars are connected to each other (end-on-end) in the Z direction. For example, the memory pillar MP may have a structure in which a lower pillar, penetrating the conductors 23 to 25, and an upper pillar, penetrating the conductors 26 to 28, are connected.

In the stepped region, the memory cell array 10 includes the conductors 21 and 23 to 28 and the plurality of contact plugs CC.

For example, end portions of the conductor 23, the conductors 24 to 27, and the conductor 28 corresponding to the select gate line SGS, the word lines WL0 to WL3, and the select gate line SGD are provided in a stepped shape (stair-step or terraced shape). However, the present disclosure is not limited thereto. In the stepped region, each end portion of the conductors 23 to 28 may have a portion that does not overlap with at least the conductors 24 to 28 provided above, that is, a connection region with the contact plug CC.

Each contact plug CC is formed in a columnar shape extending along the Z direction, and comprises a conductor 35. The conductor 35 is formed in a columnar shape extending from an upper surface to a bottom surface of the contact plug CC. The conductor 35 is, for example, tungsten (W). The bottom surface of each contact plug CC is connected to one of the conductors 23 to 28.

In the C4 region, the memory cell array 10 includes, for example, the conductor 21, the metal plug 22, and the contact plugs C4.

In the opening region OR formed in the conductor 21, the metal plug 22 is in contact with the side surface (lateral edge) of the conductor 21. The metal plug 22 is, for example, tungsten (W).

Each contact plug C4 is formed in a columnar shape extending along the Z direction, and includes a conductor 36 and a spacer 37. The conductor 36 is formed in a columnar shape extending from an upper surface to a bottom surface of the contact plug C4. The spacer 37 is formed on a side (lateral) surface of the conductor 36 and has, for example, a cylindrical shape. In other words, the side surface of the conductor 36 is covered with the spacer 37. The conductor 36 is, for example, tungsten (W). The spacer 37 is, for example, SiN. A bottom surface of the contact plug C4 is connected to a wiring layer D2 provided below the level of the memory cell array 10.

The plug region is an outer circumference region of the memory cell array 10 in which the conductors 23 to 28 are not provided. A portion of the conductor 21 and a metal plug 22 is in the plug region, for example. Furthermore, in the plug region, below the level of the memory cell array 10, the wiring layer D2 is electrically connected to the conductor 21. A contact plug C2, the wiring layer D1, and the contact plug C1 are also provided. This portion of wiring layer D2, the contact plug C2, the wiring layer D1, and the contact plug C1 are not electrically connected to transistors or the like.

In the plug region, the metal plug 22 is in contact with the side surface of the conductor 21. The metal plug 22 is, for example, tungsten (W). A lower end of the metal plug 22 is connected to the wiring layer D2.

The wiring layer D2 is connected to the wiring layer D1 through the contact plug C2. The wiring direction of the wiring layer D2 may be either the extending direction of the word line WL or the extending direction of the bit line BL. The wiring layer D1 is connected to the N⁺ diffusion layer region provided on the semiconductor substrate 20 through the contact plug C1. The number of the wiring layers and the number of the contact plugs provided in levels below the memory cell array 10 may be any number. In general, incorporation of additional connection levels are no problem as long as the metal plug 22 is electrically connected to the N⁺ diffusion layer region of the semiconductor substrate 20.

In this example, two P-type well regions are provided at the upper surface of the semiconductor substrate 20. One P-type well region is spaced apart from the other P-type well region in the X direction. The N⁺ diffusion layer region is provided between these two P-type well regions. Each of the two P-type well regions forms a PN junction between the metal plug 22 and the N⁺ diffusion layer region provided in a connection portion of the semiconductor substrate 20, and thus electrically separates the metal plug 22 from other device elements on the front surface of the semiconductor substrate 20. Thereby, it is possible to prevent the other elements on the front surface of the semiconductor substrate 20 from being influenced by potential or charge of the source line SL in a memory operation.

In the structure of the memory cell array 10, the conductors 24 to 27 correspond in number to the number of the word lines WL. Additional, conductors corresponding to additional word lines WL may be incorporated. Likewise, multiple conductors 23 may be provided in a plurality of layers for the select gate line(s) SGS. When the select gate line SGS is provided in a plurality of layers, another conductor other than the conductor 23 may be used. Similarly, multiple conductors 28 may be provided in a plurality of layers for the select gate line(s) SGD.

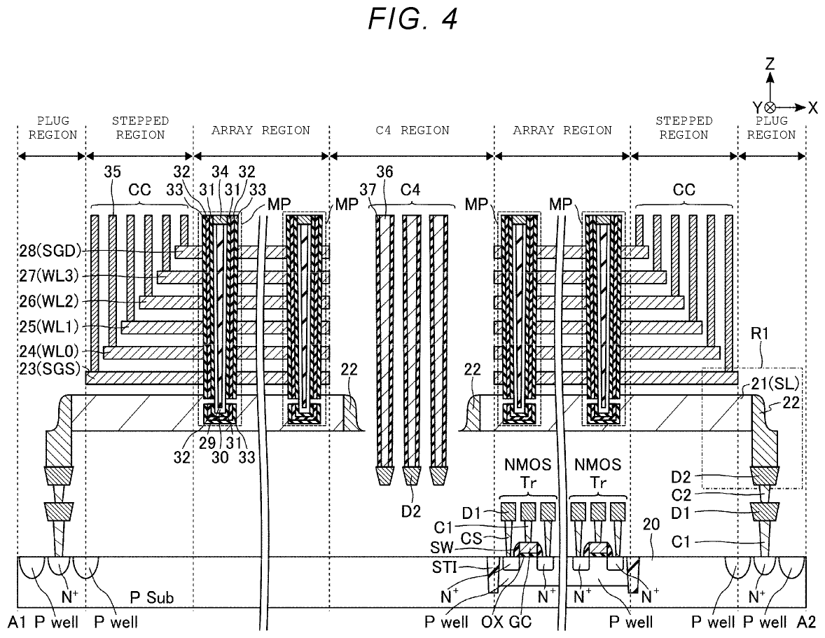

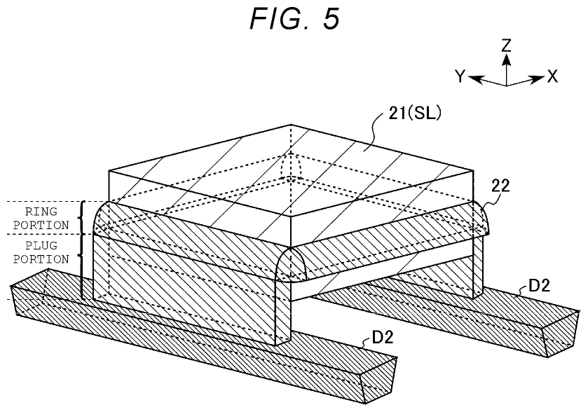

FIG. 5 illustrates an example of a three-dimensional structure of the conductor 21 and the metal plug 22 according to the first embodiment, and illustrates a portion corresponding to the block BLK0. In FIG. 5, in order to simplify the depiction, the details of the opening region OR are omitted.

As can be seen, the metal plug 22 comprises a ring portion and a plug portion.

The ring portion is in contact with the side surface of the source line SL (conductor 21) and surrounds (encircles or borders) the outer circumference of the source line SL. The plug portion electrically connects the ring portion and the wiring layer D2 below the plug portion. In the example of FIG. 5, the plug portion is provided on wires of the wiring layer D2 that extend lengthwise in the Y direction. An upper surface of the plug portion is connected to a bottom surface of the ring portion. The plug portion is not present below the X direction extending portions of the ring portion of metal plug 22.

### 1.2 Method of Manufacturing

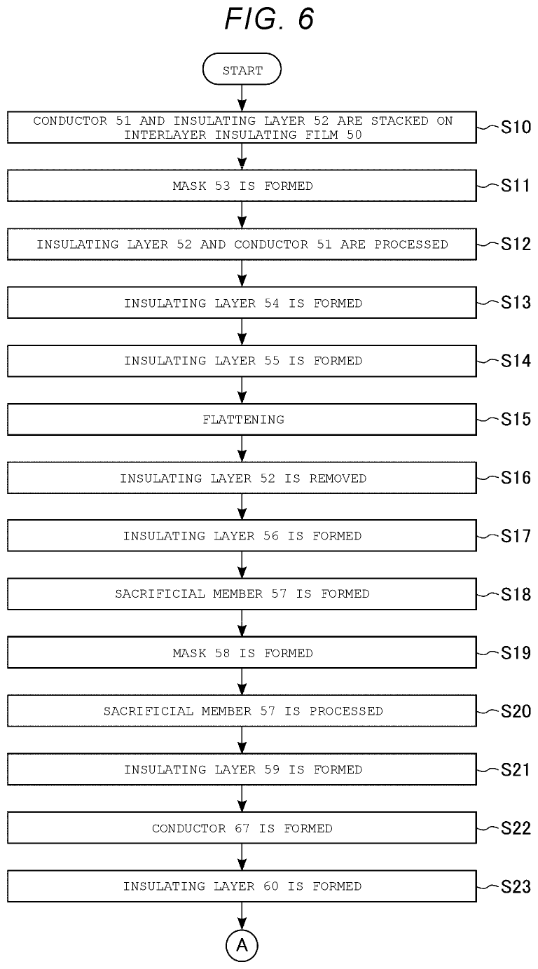

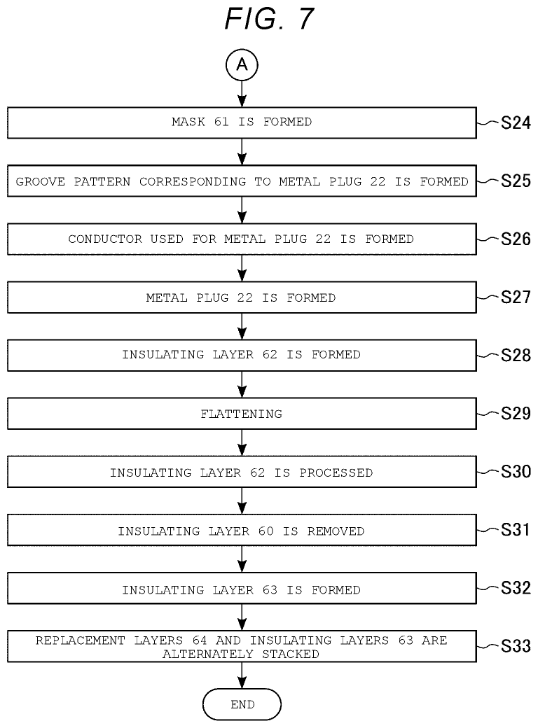

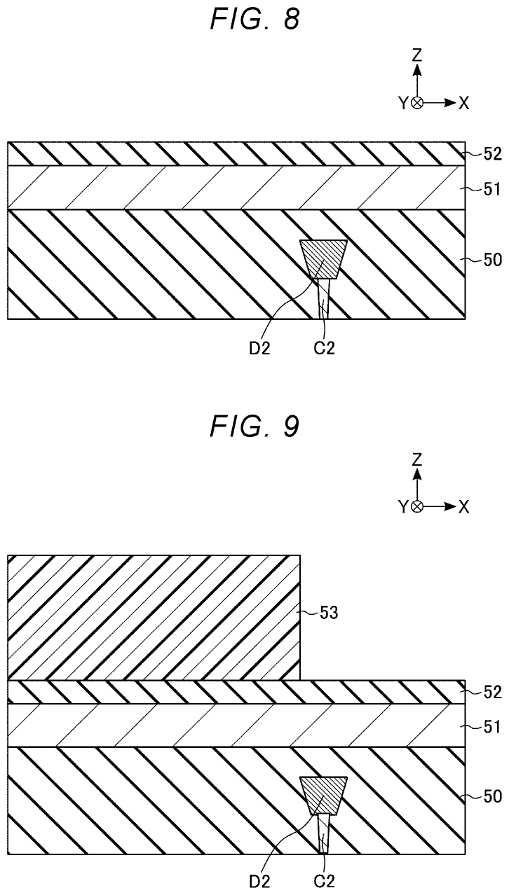

FIG. 6 and FIG. 7 are flowcharts illustrating an example of a method of manufacturing the semiconductor memory device 1 according to the first embodiment. FIG. 8 to FIG. 31 respectively illustrate a cross-sectional structure of the region R1 of FIG. 4 during various stages of a manufacturing process of the semiconductor memory device 1 according to the first embodiment.

An example of a method of manufacturing the semiconductor memory device 1 will be described with reference to FIGS. 6 and 7 and FIGS. 8 to 31, focusing on a series of steps from a step of forming the interlayer insulating film to a step of alternately stacking sacrificial layers (replacement layers) (corresponding to the conductors 23 to 28) with insulating layers.

First, as illustrated in FIG. 8, a conductor 51, which is used for a part of the source line SL, and an insulating layer 52 are stacked on an interlayer insulating film 50 in which the contact plug C2 and the wiring layer D2 are formed (step S10 in FIG. 6). Specifically, after the wiring layer D2 is formed, the interlayer insulating film 50 is formed so as to cover an upper surface of the wiring layer D2. The conductor 51 is formed on the interlayer insulating film 50. Then, the insulating layer 52 is formed on the conductor 51. The conductor 51 is, for example, poly-Si. The insulating layer 52 is, for example, SiN. The wiring layer D2 is electrically connected to the N⁺ diffusion layer region of the semiconductor substrate 20 through the contact plug C2.

Next, as illustrated in FIG. 9, a mask 53 for forming a region corresponding to the source line SL is formed on the insulating layer 52 by photolithography or the like (step S11 in FIG. 6).

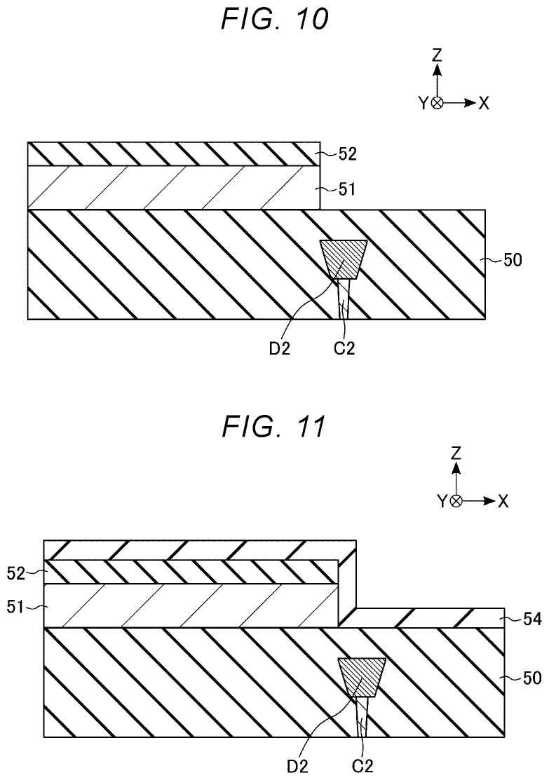

As illustrated in FIG. 10, after the insulating layer 52 and the conductor 51 are processed by anisotropic etching such as reactive ion etching (RIE), the mask 53 is removed (step S12 in FIG. 6).

Next, as illustrated in FIG. 11, an insulating layer 54 is formed on the interlayer insulating film 50 and the insulating layer 52 (step S13 in FIG. 6). The insulating layer 54 is, for example, SiO₂.

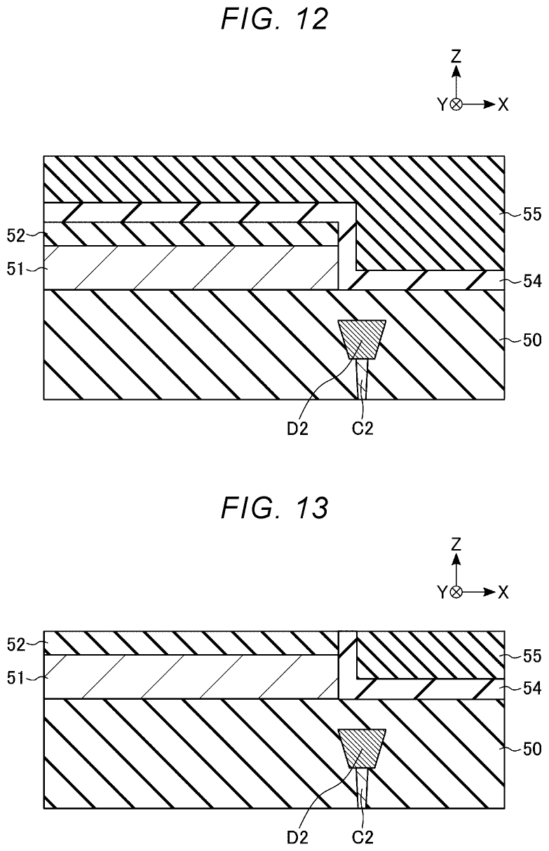

As illustrated in FIG. 12, an insulating layer 55 is formed on the insulating layer 54 (step S14 in FIG. 6). The insulating layer 55 is, for example, non-silicate glass (NSG).

Next, as illustrated in FIG. 13, an upper surface of the insulating layer 55 is flattened (planarized) by, for example, chemical mechanical polishing (CMP) (step S15 in FIG. 6). At this time, the insulating layer 52 functions as a stopper layer for CMP, and a surface of the insulating layer 52 is exposed after CMP.

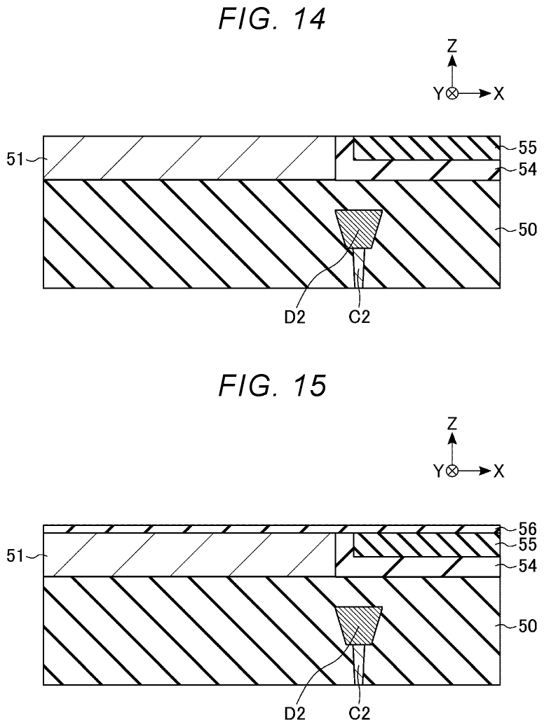

Next, as illustrated in FIG. 14, the insulating layer 52 is removed (step S16 in FIG. 6). At this time, for example, by etch-back processing using etching conditions with low material selectivity, the insulating layer 54 and the insulating layer 55 are partially removed together with the insulating layer 52.

Next, as illustrated in FIG. 15, an insulating layer 56 is formed (step S17 in FIG. 6). The insulating layer 56 is, for example, SiO₂.

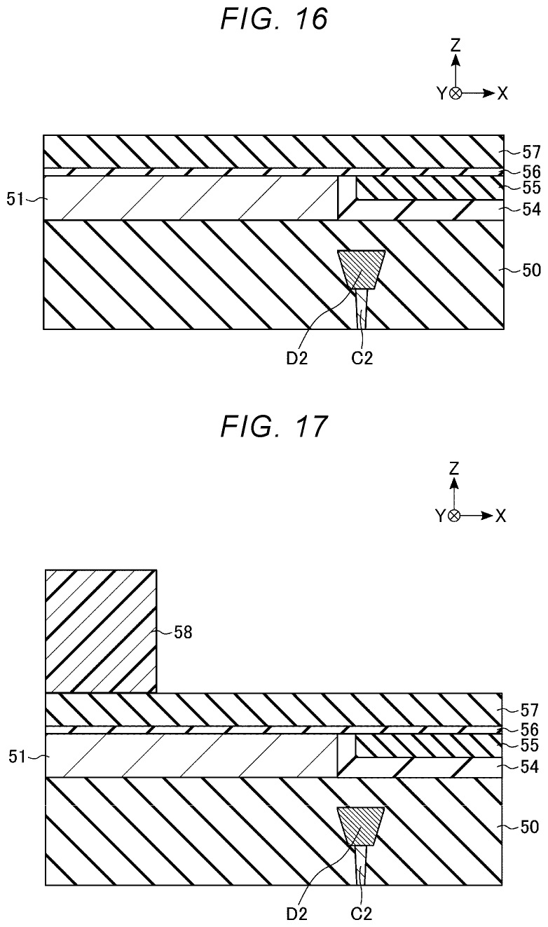

As illustrated in FIG. 16, a sacrificial member 57 is formed on the insulating layer 56 (step S18 in FIG. 6). The sacrificial member 57 is removed for forming a connection portion between the source line SL and the memory pillar MP. The sacrificial member 57 is, for example, SiN.

As illustrated in FIG. 17, a mask 58 is formed on the sacrificial member 57 by photolithography or the like (step S19 in FIG. 6) . At this time, a mask region of the resist mask 58 is formed to be smaller than a region of the conductor 51 in consideration of possible variations due to alignment accuracy and the like.

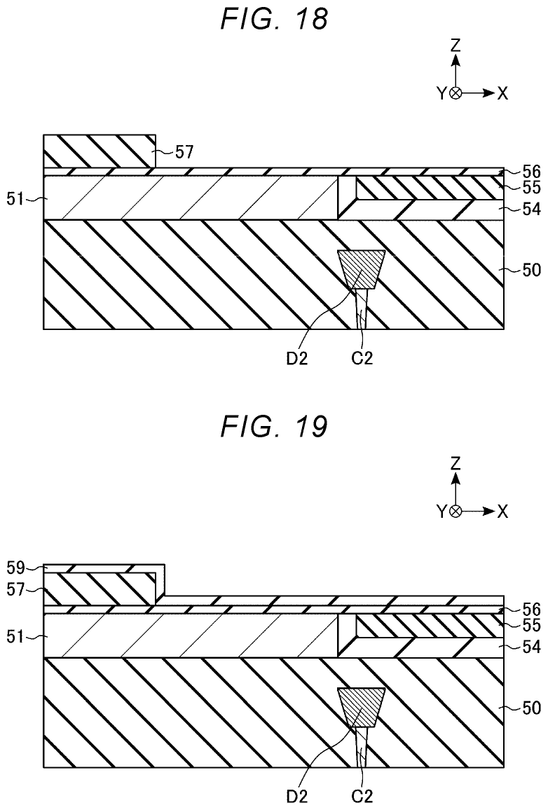

Next, as illustrated in FIG. 18, after processing the sacrificial member 57 by anisotropic etching such as RIE, the mask 58 is removed (step S20 in FIG. 6).

Next, as illustrated in FIG. 19, an insulating layer 59 is formed (step S21 in FIG. 6). The insulating layer 59 is, for example, SiO₂.

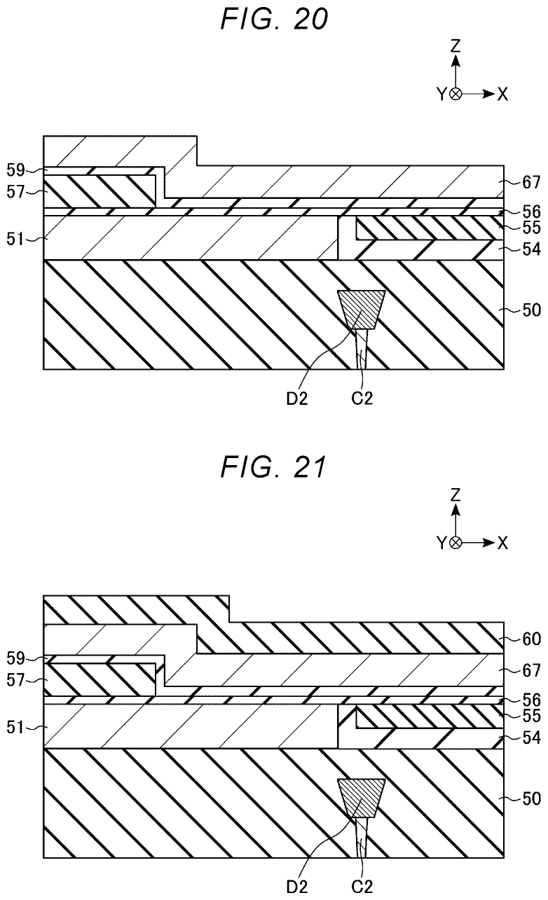

Next, as illustrated in FIG. 20, a conductor 67, which is used for a part of the source line SL, is formed on the insulating layer 59 (step S22 in FIG. 6). The conductor 67 is, for example, poly-Si.

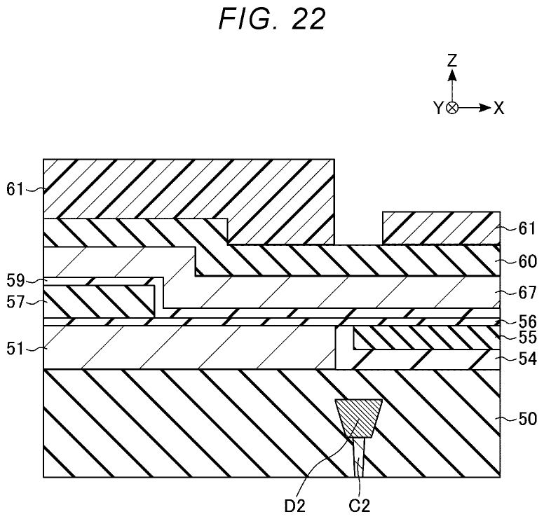

As illustrated in FIG. 21, an insulating layer 60 is formed on the conductor 67 (step S23 in FIG. 6). The insulating layer 60 is, for example, SiN.

As illustrated in FIG. 22, a mask 61 is formed by nanoimprint lithography (NIL) (step S24 in FIG. 7). The mask 61 has an opening in a region corresponding to the plug portion of the metal plug 22. Further, the mask 61 has different mask heights in a region corresponding to the source line SL and a region outside the source line SL (including a region in which the plug portion of the metal plug 22 is not provided). More specifically, the height of the mask 61 is greater in the region corresponding to the source line SL than in the region outside the source line SL.

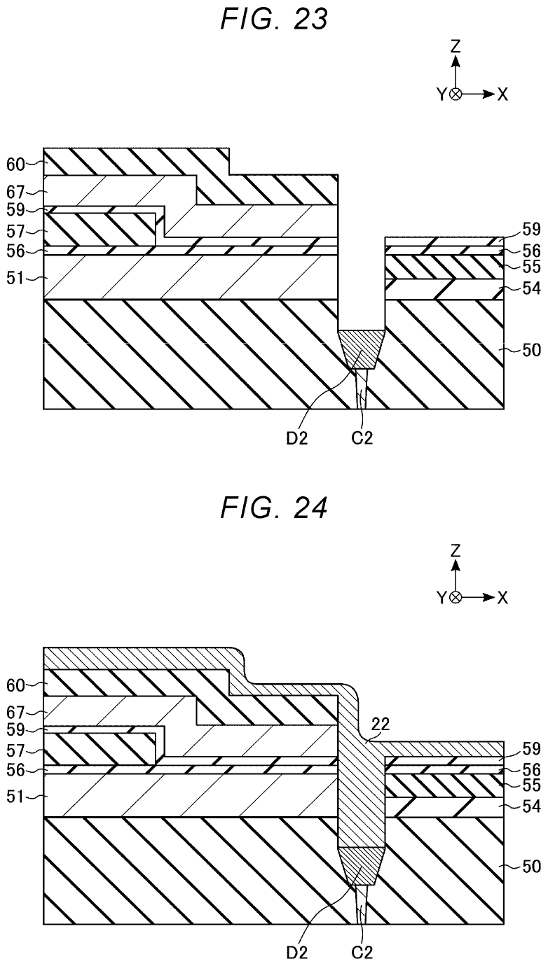

As illustrated in FIG. 23, a groove pattern corresponding to the metal plug 22 is formed by anisotropic etching such as RIE. Thereafter, the mask 61 is removed (step S25 in FIG. 7). Specifically, for example, in the region corresponding to the plug portion of the metal plug 22, a groove pattern of which the bottom surface reaches the wiring layer D2 is formed. In the region corresponding to the source line SL, the insulating layer 60 is not etched. In the region outside the source line SL, the insulating layer 60 and the conductor 67 are removed. In the region in which the plug portion of the metal plug 22 is not provided, the insulating layer 60 and the conductor 67 are removed. Therefore, in the region in which the plug portion of the metal plug 22 is not provided, a corner portion is formed between side surfaces of the insulating layer 60 and the conductor 67 in the region corresponding to the source line SL and an upper surface of the insulating layer 59.

The insulating layer 56, the sacrificial member 57, and the insulating layer 59 in the region corresponding to the source line SL are removed when forming a connection region between the semiconductor 30 and the conductor 21 in the manufacturing process of the memory pillar MP. A gap formed by removing the insulating layer 56, the sacrificial member 57, and the insulating layer 59 is filled with a conductive material. The conductor 21, that is, the source line SL includes the conductive material, the conductor 51, and the conductor 67.

Next, as illustrated in FIG. 24, a conductor used for the metal plug 22 is formed, and the groove pattern is filled (step S26 in FIG. 7). At this time, the conductor used for the metal plug 22 is also formed on the insulating layer 59 and the insulating layer 60.

Next, as illustrated in FIG. 25, the metal plug 22 is formed (step S27 in FIG. 7). Specifically, the conductor material for metal plug 22 deposited on the insulating layer 59 and the insulating layer 60 is removed by, for example, an etch-back process. The metal plug 22 fills the groove pattern in the region corresponding to the plug portion, is in contact with side surfaces of the conductor 67 and the conductor 51, and hangs (extends) from the conductor 67 toward the insulating layer 55. The metal plug 22 remains on a corner portion, which is formed by the side surface of the conductor 67 in the region corresponding to the source line SL and the upper surface of the insulating layer 59, in the region in which the plug portion is not provided. That is, the metal plug 22 is formed so as to surround the region corresponding to the source line SL.

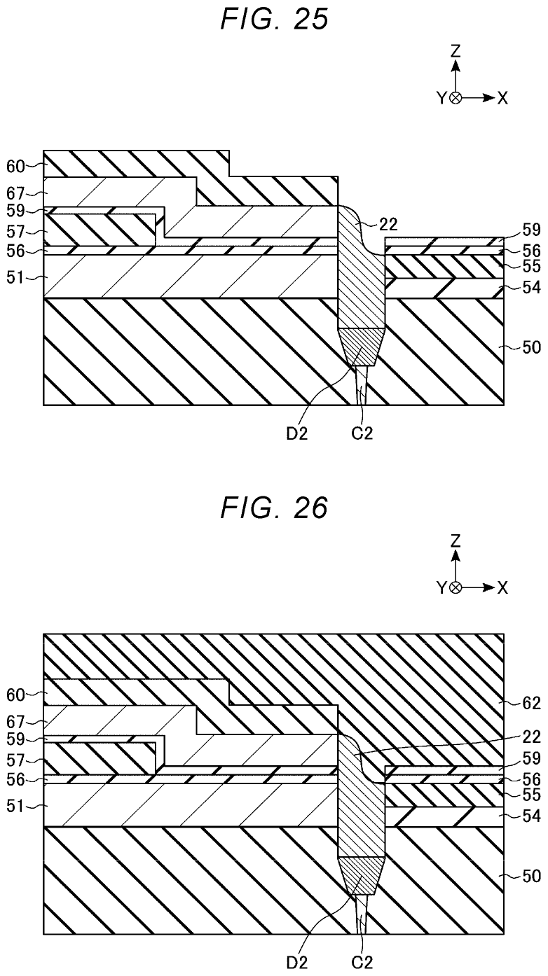

Next, as illustrated in FIG. 26, an insulating layer 62 is formed (step S28 in FIG. 7). The insulating layer 62 is, for example, non-silicate glass (NSG).

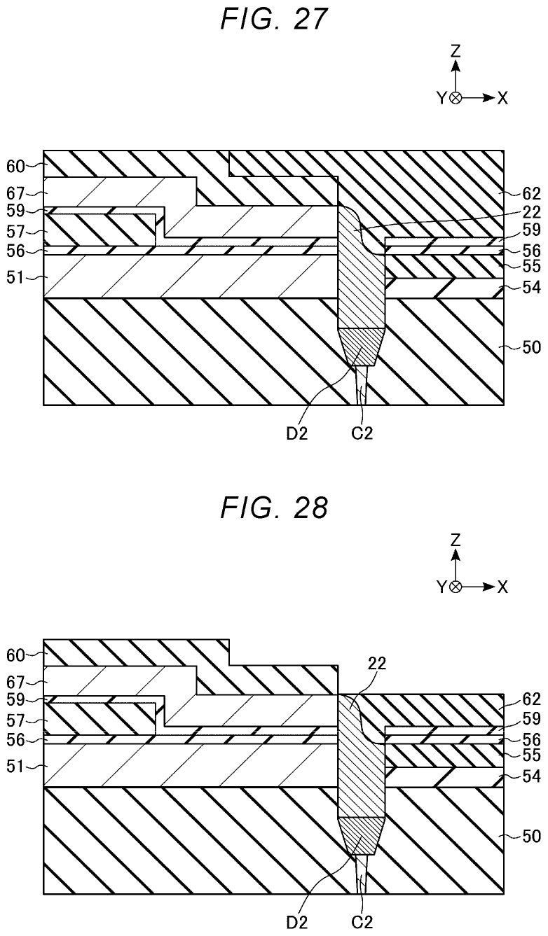

Next, as illustrated in FIG. 27, the upper surface is polished by, for example, CMP (step S29 in FIG. 7). At this time, a part of an upper surface of the insulating layer 60 is exposed.

Next, as illustrated in FIG. 28, a part of the insulating layer 62 is processed by, for example, an etch-back process such that the upper surface of the insulating layer 60 is exposed in the region corresponding to the source line SL (step S30 in FIG. 7).

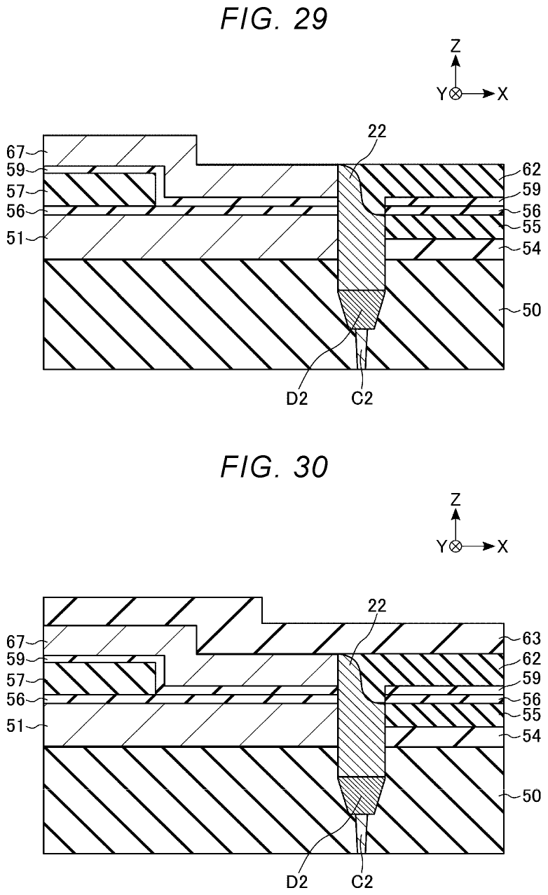

As illustrated in FIG. 29, the insulating layer 60 is removed by anisotropic etching such as RIE (step S31 in FIG. 7).

As illustrated in FIG. 30, an insulating layer 63 is formed (step S32 in FIG. 7). The insulating layer 63 is, for example, SiO₂.

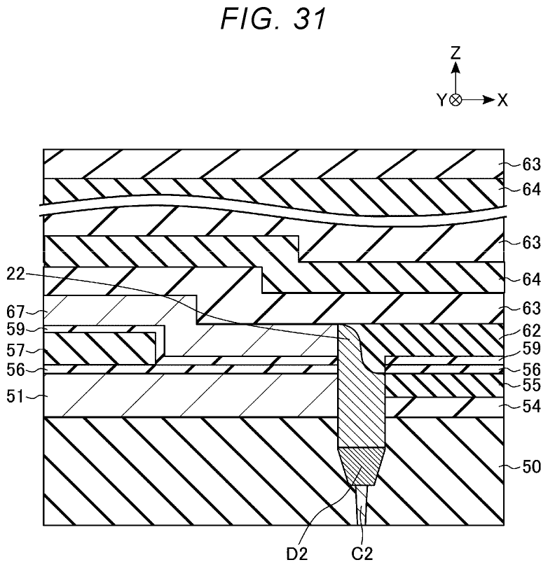

Next, as illustrated in FIG. 31, six replacement layers 64 (corresponding to the conductors 23 to 28) and six insulating layers 63 are alternately stacked (step S33 in FIG. 7). The six replacement layers 64 are ultimately replaced with the conductors 23 to 28 in the subsequent manufacturing process. The replacement layers 64 may also be referred to as sacrificial layers or the like. In the subsequent manufacturing processes, the conductors 23 to 28 are formed at positions correspond to those of the six replacement layers 64. By filling gaps left by removal of the replacement layers 64 with a conductive material, the conductors 23 to 28 can be formed. The replacement layer 64 is, for example, SiN.

### 1.3 Effects

According to the semiconductor memory device 1 of the first embodiment, it is possible to improve or maintain yield of the semiconductor memory device 1. Hereinafter, certain details related to this effect will be described.

In a structure in which circuits, such as a row decoder module and a sense amplifier module, are provided on a semiconductor substrate and a memory cell array is provided above the semiconductor substrate, the source line may not be connected to the semiconductor substrate. In such a case, when holes corresponding to the memory pillars are being formed by, for example, RIE, positive charges may accumulate in the conductor corresponding to the source line, and as a result, arcing (an abnormal discharge) may occur. When arcing occurs, a pattern abnormality (defect) occurs, and as a result, product yield will be decreased.

However, in the semiconductor memory device 1 according to the first embodiment, the metal plug 22 is formed. This metal plug 22 is in contact with the outer circumferential side surface of the source line SL, and is connected to the upper surface of the wiring layer D2 provided below. The wiring layer D2 is electrically connected to the N⁺ diffusion layer region of the semiconductor substrate 20 through the lower layer wiring. According to this structure, positive charges accumulated in the source line SL during formation steps of the memory pillar MP can be discharged to the semiconductor substrate 20 through the metal plug 22, the wiring layer D2, and the lower layer wiring. Therefore, a static charge elimination effect of the source line SL can be improved. Thereby, it is possible to prevent a decrease in yield of the semiconductor memory device 1 due to arcing or the like.

With the configuration according to the first embodiment, the metal plug 22 is in contact with the entire outer circumference surface of the conductor 21 corresponding to the source line SL. According to this structure, the contact area between the conductor 21 and the metal plug 22 is increased. Therefore, the static charge elimination effect of the semiconductor memory device 1 is improved.

Furthermore, with the configuration according to the first embodiment, the metal plug 22 is electrically connected to the N⁺ diffusion layer region of the p-type semiconductor substrate. Therefore, when a voltage is applied to the source line SL in a write operation or the like, the current is unlikely to flow to the semiconductor substrate side.

Additionally, according to the method of manufacturing the semiconductor memory device 1 of the first embodiment, the mask 61 is formed using NIL when processing the groove pattern of the metal plug 22, and thus it is possible to prevent an increase in the number of steps of the manufacturing process that might otherwise be due to addition of the metal plug 22.

### 2. Second Embodiment

A semiconductor memory device 1 according to a second embodiment will be described. This second embodiment is obtained by modifying a part of the manufacturing process of the semiconductor memory device 1 of the first embodiment. Hereinafter, a description of the second embodiment will be given focusing on differences from the first embodiment.

### 2.1 Method of Manufacturing

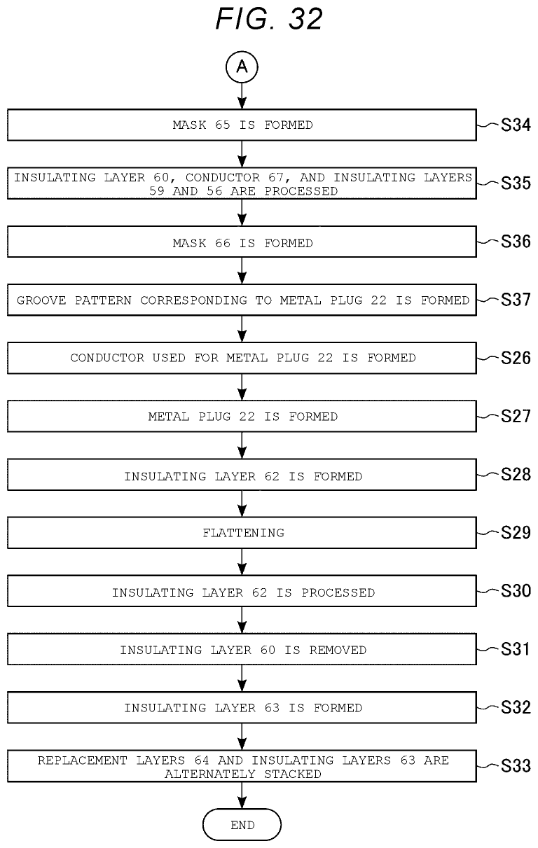

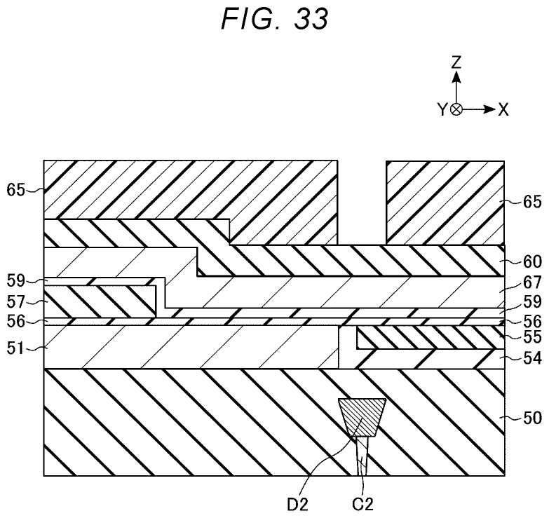

FIG. 32 is a flowchart illustrating an example of a method of manufacturing the semiconductor memory device 1 according to the second embodiment. FIG. 33 to FIG. 35 each illustrate a cross-section of the structure in the region R1 of FIG. 4 during the manufacturing process of the semiconductor memory device 1 according to the second embodiment. The flowchart of FIG. 32 illustrates a process flow following step S23 of the flowchart of FIG. 6.

A method of manufacturing the semiconductor memory device 1 according to the second embodiment will be described with reference to FIG. 32 and FIGS. 33 to 35 by focusing on those steps or aspects different from the first embodiment.

First, similarly to the first embodiment, steps S10 to S23 of FIG. 6 are performed. After forming the insulating layer 60 in step S23 of FIG. 6, a mask 65 having an opening in a region corresponding to the metal plug 22 is formed on the insulating layer 60 by photolithography or the like (step S34 in FIG. 32). Mask 65 is depicted in FIG. 33.

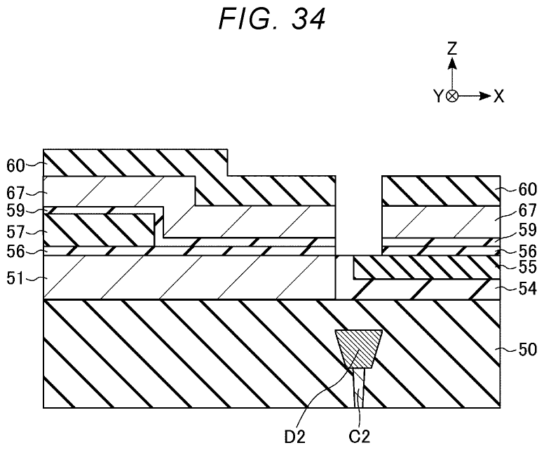

Next, as illustrated in FIG. 34, after the insulating layer 60, the conductor 67, and the insulating layers 59 and 56 are etched by, for example, RIE, the mask 65 is removed (step S35 in FIG. 32).

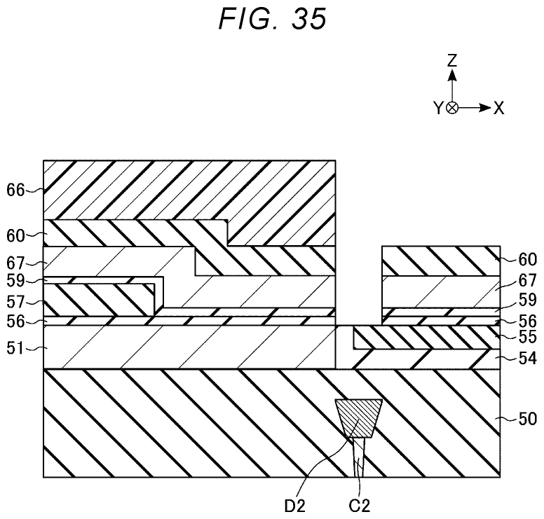

Next, as illustrated in FIG. 35, by photolithography or the like, a mask 66, which has an opening in a region corresponding to the plug portion of the metal plug 22 and also a region outside the source line SL, is formed (step S36 in FIG. 32).

Next, similarly to FIG. 23 of the first embodiment, a groove pattern corresponding to the metal plug 22 is formed. Thereafter, the mask 66 is removed (step S37 in FIG. 32).

The subsequent flow is the same as steps S26 to S33 of the first embodiment.

### 2.2 Effects According to Second Embodiment

Substantially the same effects as the first embodiment can be obtained with the second embodiment.

### 3. Modification Example

As described above, the semiconductor memory device according to the first and second embodiments includes a layered first conductor SL provided above the substrate 20, a plurality of second conductors 23 to 28 that are disposed above the first conductor and are stacked but separated from each other in a first direction (Z direction), a plurality of pillars that extend in the first direction (Z direction), pass through the plurality of second conductors, and include a layered semiconductor electrically connected to the first conductor, and a first metal plug 22 that surrounds an outer circumference of the first conductor and electrically connects the first conductor and the substrate.

The possible embodiments are not limited to the above-described form, and various modifications may be made.

A structure in which a part of the side surface of the semiconductor 30 of the memory pillar MP is in contact with the conductor 21 corresponding to the source line SL has been described as an example. However, the present disclosure is not limited thereto.

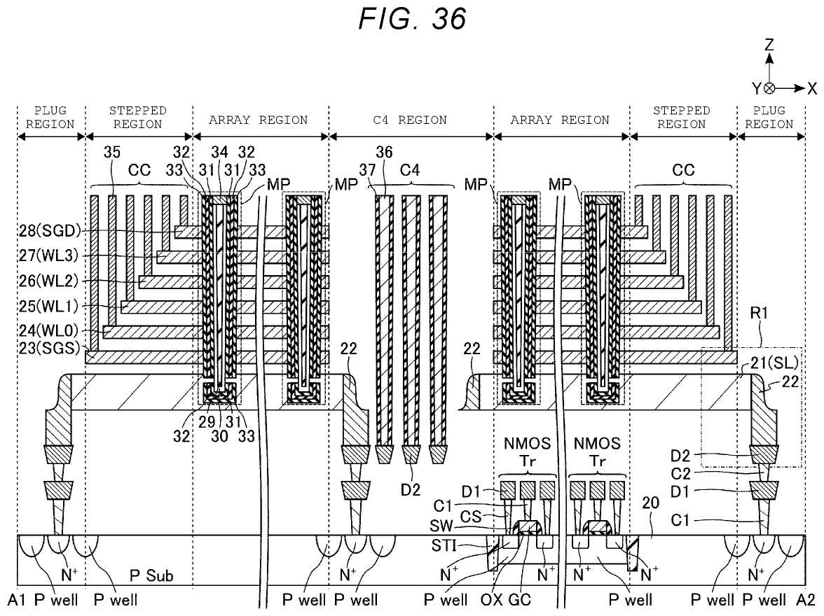

Additionally, as illustrated in FIG. 36, in the opening region OR of the source line SL in the C4 region, the metal plug 22, which is in contact with the side surface of the conductor 21, may include a plug portion, which may be connected to the lower wiring layer D2, which may be electrically connected to the semiconductor substrate 20 via a contact plug C1. Thus, the metal plug 22 is electrically connected to the semiconductor substrate 20 via a plug portion formed in a region corresponding to the opening region OR. In this case, available current paths between the conductor 21 and the semiconductor substrate are further increased, and thus the static charge elimination effect of the source line SL can be further improved.

In this specification, “connection” indicates electrical connection, and does not exclude electrical connection through another component.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein maybe made without departing from the spirit of the present disclosure. The accompanying claims and their equivalents are intended to cover such forms or modifications as would fall within the scope and spirit of the present disclosure.

What is claimed is:

1. A semiconductor memory device, comprising:
a first conductor layer above a substrate in a first direction;
a plurality of second conductor layers stacked above the first conductor layer in the first direction, the second conductor layers being spaced from each other in the first direction;
a plurality of pillars that extend through the plurality of second conductor layers in the first direction, each pillar including a semiconductor layer electrically connected to the first conductor layer; and
a first metal plug that surrounds an outer circumference of the first conductor layer and electrically connects the first conductor layer to the substrate.

2. The semiconductor memory device according to claim 1, further comprising:
a first wiring layer between the substrate and the first conductor layer in the first direction, wherein
the first metal plug includes a first portion that is in contact with a side surface of the first conductor layer and a second portion that electrically connects the first portion to the first wiring layer, and
the first wiring layer is electrically connected to the substrate.

3. The semiconductor memory device according to claim 2, wherein
the first wiring layer is parallel to the substrate and extends in a second direction intersecting with the first direction, and
the second portion directly contacts the first wiring layer.

4. The semiconductor memory device according to claim 1, further comprising:
a first plug that passes through the plurality of second conductor layers and an opening in the first conductor layer, the first plug having a side surface, which is not in contact with the first conductor layer and the plurality of second conductor layers.

5. The semiconductor memory device according to claim 4, further comprising:
a second metal plug that is in contact with the first metal plug at the opening in the first conductor layer.

6. The semiconductor memory device according to claim 5, further comprising:
a second wiring layer between the substrate and the first conductor layer in the first direction, wherein
the second metal plug electrically connects the first conductor layer and the second wiring layer, and
the second wiring layer is electrically connected to the substrate.

7. The semiconductor memory device according to claim 1, wherein
each of the plurality of pillars further includes a charge storage layer, and
an end of each semiconductor layer of each pillar extending into the first conductor layer and electrically connected to the first conductor layer.

8. The semiconductor memory device according claim 1, wherein the first metal plug comprises tungsten.

9. The semiconductor memory device according to claim 1, wherein the first metal plug comprises a ring portion adjacent to each lateral edge of the first conductor layer and a plug portion that extends in the first direction toward the substrate from the ring portion on a first lateral edge of the first conductor layer.

10. The semiconductor memory device according to claim 9, wherein
the first lateral edge of the first conductor layer extends in a second direction parallel to the substrate and intersecting the first direction, and
the plug portion extends in the second direction for substantially the entire length of the first lateral edge in the second direction.

11. The semiconductor memory device according to claim 10, wherein the first metal plug further comprises a second plug portion that extends in the first direction toward the substrate from the ring portion on a second lateral edge of the first conductor layer opposite the first lateral edge in a third direction parallel to the substrate orthogonal to the first and second directions.

12. A semiconductor memory device, comprising:
a first conductor layer above a semiconductor substrate in a first direction;
a plurality of second conductor layers stacked above the first conductor layer in the first direction, the second conductor layers being spaced from each other in the first direction and having stair-stepped ends in a second direction parallel to the semiconductor substrate;
a plurality of pillars that extend in the first direction through the plurality of second conductor layers in a memory array region, each pillar including a semiconductor layer electrically connected to the first conductor layer and a charge storage layer, memory cells being at positions along each pillar at which second conductors layers are adjacent;
a contact plug extending in the first direction through the plurality of second conductor layers and an opening in the first conductor layer in a contact plug region, the contact plug electrically contacting a first wire in a first wiring layer between the first conductor layer and the semiconductor substrate in the first direction; and
a first metal plug that surrounds a perimeter of the first conductor layer and electrically connects the first conductor layer to the semiconductor substrate.

13. The semiconductor memory device according to claim 12, wherein
the first metal plug includes a first portion that is in contact with a side surface of the first conductor layer and a second portion that extends in the first direction electrically connects the first portion to a second wire in the first wiring layer, and
the second wire is electrically connected to the semiconductor substrate.

14. The semiconductor memory device according to claim 12, wherein the first metal plug comprises a ring portion adjacent to each lateral edge of the first conductor layer and a first plug portion that extends in the first direction toward the semiconductor substrate from the ring portion on a first lateral edge of the first conductor layer.

15. The semiconductor memory device according to claim 14, wherein
the first conductor layer extends beyond the stair-stepped ends of the plurality of second conductor layers to a plug region, and
the first plug portion is in the plug region.

16. The semiconductor memory device according to claim 15, wherein the first metal plug further comprises a second plug portion that extends in the first direction toward the semiconductor substrate from the ring portion on a second lateral edge of the first conductor layer that is at the opening.

17. A semiconductor memory device, comprising:
a source conductor layer above a semiconductor substrate in a first direction;
a plurality of gate electrode layers stacked above the source conductor layer in the first direction, the gate electrode layers being spaced from each other in the first direction;
a plurality of memory pillars that extend through the plurality of gate electrode layers in the first direction, each memory pillar including a semiconductor layer having an end electrically connected to the source conductor layer; and
a first metal plug that surrounds an outer perimeter of the source conductor layer and electrically connects the source conductor layer to the semiconductor substrate.

18. The semiconductor memory device according to claim 17, further comprising:
a first wiring layer between the semiconductor substrate and the source conductor layer in the first direction, wherein
the first metal plug includes a first portion that is in contact with a side surface of the source conductor layer and a second portion that electrically connects the first portion to a wire in the first wiring layer, and
the wire is electrically connected to the semiconductor substrate.

19. The semiconductor memory device according to claim 18, wherein
the first wiring layer is parallel to the substrate and the wire extends in a second direction intersecting with the first direction, and
the second portion directly contacts the wire in the first wiring layer.

20. The semiconductor memory device according to claim 17, further comprising:
a contact plug that passes through the plurality of gate electrode layers and an opening in the source conductor layer, the contact plug having a side surface which is not in contact with the source conductor layer and the plurality of gate electrode layers.
